(19) United States
(12) Patent Application Publication
(10) Pub. No.: US 2024/0429176 A1
(43) Pub. Date: Dec. 26, 2024

(54) SEMICONDUCTOR PACKAGE AND MANUFACTURING METHOD THEREOF

(71) Applicant: Samsung Electronics Co., Ltd., Suwon-si (KR)

(72) Inventors: JU-IL CHOI, Suwon-si (KR); KWANGOK JEONG, Suwon-si (KR); JAEMOK JUNG, Suwon-si (KR); JEONGGI JIN, Suwon-si (KR); TAE OH HA, Suwon-si (KR); HONGSEO HEO, Suwon-si (KR)

(21) Appl. No.: 18/417,494

(22) Filed: Jan. 19, 2024

(30) Foreign Application Priority Data
Jun. 26, 2023 (KR) 10-2023-0082144

(51) Int. Cl. H01L 23/544; H01L 21/48; H01L 23/00; H01L 23/498; H01L 23/538

(52) U.S. Cl. CPC H01L 23/544; H01L 21/4857; H01L 23/49811; H01L 23/5383; H01L 24/16; H01L 2223/54426; H01L 2224/16225

(57) ABSTRACT

A semiconductor package including: a first redistribution structure; a semiconductor chip on the first redistribution structure; a pad insulation layer on a lower surface of the first redistribution structure; a conductive pad extending into a lower surface of the pad insulation layer and electrically connected to the first redistribution structure; and a plurality of alignment patterns on an edge of the pad insulation layer, each of the plurality of alignment patterns including a first portion extending into a lower surface of the pad insulation layer and a second portion extending away from the lower surface of the pad insulation layer.

### CROSS-REFERENCE TO RELATED APPLICATION

This application claims priority to and the benefit of Korean Patent Application No. 10-2023-0082144 filed on Jun. 26, 2023, in the Korean Intellectual Property Office, the entire contents of which are incorporated herein by reference.

### BACKGROUND

### 1. Field

The present disclosure relates to a semiconductor package and a manufacturing method thereof.

### 2. Description of the Related Art

The semiconductor industry field is pursuing improvement in integration density so that more passive or active devices may be integrated in a given area. However, as technology development for miniaturizing a circuit line width of an entire semiconductor process is gradually facing limitations, in the semiconductor industry field, a semiconductor package that protects a semiconductor chip on which an integrated circuit is formed is lightweight, thin, miniaturized, high-speed, and multifunctional, and there is a trend to supplement the limitations of the entire semiconductor process by developing a semiconductor package with high integration density.

The semiconductor package described above may be mounted on a board to be electrically connected to the board. In this case, it is required to accurately position the semiconductor package so that the semiconductor package is accurately connected between the boards.

### SUMMARY

According to some embodiments, efficiency of functioning as an alignment mark or alignment key may be increased. Accordingly, reliability of the semiconductor package may be improved.

Some embodiments provide a semiconductor package including: a first redistribution structure; a semiconductor chip on the first redistribution structure; a pad insulation layer on a lower surface of the first redistribution structure; a conductive pad extending into a lower surface of the pad insulation layer and electrically connected to the first redistribution structure; and a plurality of alignment patterns on an edge of the pad insulation layer, each of the plurality of alignment patterns including a first portion extending into a lower surface of the pad insulation layer and a second portion extending away from the lower surface of the pad insulation layer.

Some embodiments provide a semiconductor package including: a first redistribution structure including an active area and a dummy area around the active area; a semiconductor chip on the first redistribution structure in the active area; a second redistribution structure on the semiconductor chip; a conductive post connecting an upper surface of the first redistribution structure and a lower surface of the second redistribution structure, in the active area; a pad insulation layer on a lower surface of the first redistribution structure; a conductive pad extending into a lower surface of the pad insulation layer and electrically connected to the first redistribution structure, in the active area; a solder extending away from a lower surface of the conductive pad; and a plurality of alignment patterns, each of the plurality of alignment patterns including a first portion extending into the lower surface of the pad insulation layer and a second portion extending away from the lower surface of the pad insulation layer, in the dummy area, wherein a width of the first portion is greater than that of the second portion.

Some embodiments provide a manufacturing method of a semiconductor package, including: patterning a trench on one surface of a carrier substrate; forming a mask pattern having a first opening exposing the trench on the carrier substrate; forming an alignment pattern on the trench exposed by the first opening; forming a first redistribution structure on the alignment pattern; and mounting a semiconductor chip on the first redistribution structure.

According to some embodiments, since a semiconductor package includes an alignment pattern extending away from a pad insulation layer, efficiency of functioning as an alignment mark or align key may be increased. Accordingly, reliability of the semiconductor package may be improved.

### BRIEF DESCRIPTION OF THE DRAWINGS

FIG. 1 illustrates a cross-sectional view of a semiconductor package according to some embodiments.

FIG. 2 illustrates a cross-sectional view of an enlarged alignment pattern of a semiconductor package according to some embodiments.

FIG. 3 illustrates a cross-sectional view of an enlarged alignment pattern of a semiconductor package according to some embodiments.

FIG. 4 illustrates a bottom view of a semiconductor package device according to some embodiments.

FIG. 5 illustrates a cross-sectional view of a semiconductor package according to some embodiments.

FIG. 6 to FIG. 16 illustrate cross-sectional views of a manufacturing method of a semiconductor package according to some embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

Further, in the drawings, the size and thickness of each element are arbitrarily illustrated for ease of description, and the present disclosure is not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means on or below the object portion, and does not necessarily mean on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor package according to some embodiments will be described with reference to the accompanying drawings.

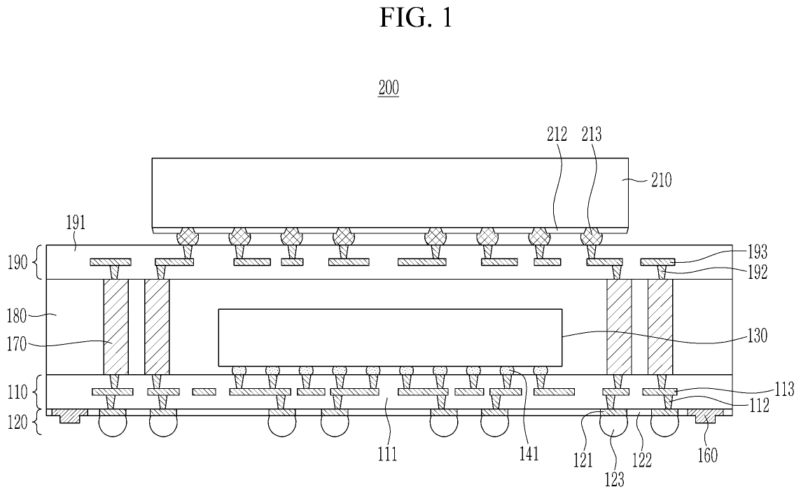

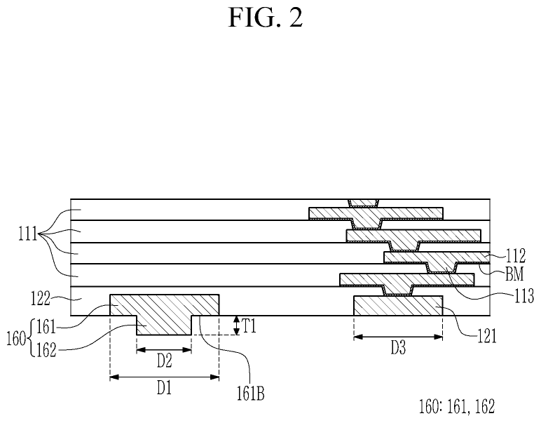

FIG. 1 illustrates a cross-sectional view of a semiconductor package according to some embodiments. FIG. 2 illustrates a cross-sectional view of an enlarged alignment pattern of a semiconductor package according to some embodiments.

Referring to FIG. 1, a semiconductor package 200 according to some embodiments may include a first redistribution structure 110, an external connection structure 120, a first semiconductor chip 130, a conductive post 170, a molding material 180, a second redistribution structure 190, and a second semiconductor chip 210.

In some embodiments, the semiconductor package 200 may include a package on package (POP). In some embodiments, the semiconductor package 200 may include a fan out wafer level package (FOWLP) or a fan out panel level package (FOPLP).

The first redistribution structure 110 may include a first insulation layer 111, a plurality of first redistribution vias 112 within the first insulation layer 111, and a plurality of first redistribution lines 113.

The first insulation layer 111 may protect and insulate the plurality of first redistribution vias 112 and the plurality of first redistribution lines 113. The first semiconductor chip 130 and the conductive post 170 may be on an upper surface of the first insulation layer 111. The external connection structure 120 may be on a lower surface of the first insulation layer 111.

The plurality of first redistribution vias 112 may be respectively between the plurality of first redistribution lines 113, between the plurality of first redistribution lines 113 and a conductive pad 121 of the external connection structure 120, and between the plurality of first redistribution lines 113 and the conductive posts 170. The plurality of first redistribution vias 112 may electrically connect the plurality of first redistribution lines 113, the plurality of first redistribution lines 113 and the conductive pad 121, and the plurality of first redistribution lines 113 and the conductive post 170, in a vertical direction.

The plurality of first redistribution lines 113 may extend in a horizontal direction. The plurality of first redistribution lines 113 may be between the plurality of first redistribution vias 112. The plurality of first redistribution lines 113 may electrically connect the plurality of first redistribution vias 112 in the horizontal direction.

In addition, as shown in FIG. 2, the semiconductor package 200 according to some embodiments may further include a barrier conductive layer BM that is on a lower surface of the plurality of first redistribution lines 113 and on lower and side surfaces of the plurality of first redistribution vias 112. The barrier conductive layer BM may be a plating seed layer on which the plurality of first redistribution lines 113 and the plurality of first redistribution vias 112 are deposited.

The external connection structure 120 may be on the lower surface of the first redistribution structure 110. The external connection structure 120 may include a conductive pad 121, a pad insulation layer 122, a solder 123, and an alignment pattern 160.

Further referring to FIG. 2, a pad insulation layer 122 may be on the lower surface of the first redistribution structure 110. The pad insulation layer 122 may prevent a short circuit between the conductive pads 121 and between the conductive pad 121 and the alignment pattern 160. The pad insulation layer 122 may include at least one of a silicon-based insulator such as a silicon oxide or silicon nitride, a polymer such as PBO, BCB, or polyimide, and a nitride such as PSG or BPSG.

The conductive pad 121 may be embedded on a lower surface of the pad insulation layer 122. That is, the conductive pad 121 may extend into or penetrate at least a portion of the pad insulation layer 122. Accordingly, the pad insulation layer 122 may cover side and upper surfaces of the conductive pad 121. The lower surface of the conductive pad 121 may be aligned on the same boundary as the lower surface of the pad insulation layer 122. For example, the lower surface of the conductive pad 121 may be at a level substantially equivalent to the lower surface of the pad insulation layer 122. The conductive pad 121 may be electrically connected to the first redistribution structure 110.

The semiconductor package 200 according to some embodiments may further include a via on the conductive pad 121. The via may be between the conductive pad 121 and the first redistribution structure 110. The via may electrically connect the conductive pad 121 and the plurality of first redistribution lines 113 of the first redistribution structure 110. However, it is not limited thereto, and the conductive pad 121 may pass through the pad insulation layer 122 to directly contact the plurality of first redistribution vias 112 and/or the plurality of first redistribution lines 113 thereof.

The conductive pad 121 may include an electrical conductivity material. For example, the conductive pad 121 may include at least one of Cu, Ni, Au, Cr, Al, Ag, Zn, and Fe.

The solder 123 may electrically connect the semiconductor package 200 to an external device. For example, the solder 123 may electrically connect the semiconductor package 200 to an external device (for example, a board on which the semiconductor package is mounted) through the conductive pad 121.

The alignment pattern 160 may be embedded on/extend into the lower surface of the pad insulation layer 122. For example, a portion of the alignment pattern 160 may extend into or penetrate at least a portion of the pad insulation layer 122, and the remaining portion of the alignment pattern 160 may protrude from or extend away from the lower surface of the pad insulation layer 122. The alignment pattern 160 may have a step in a portion protruding from or extending away from the lower surface of the pad insulation layer 122. The alignment pattern 160 may be outside the conductive pad 121. The alignment pattern 160 may be on the edge of the pad insulation layer 122. The alignment pattern 160 may not be electrically connected to the first redistribution structure 110.

According to some embodiments, in a process of mounting the semiconductor package 200 on a board, the alignment pattern 160 may function as an alignment mark or an align key. That is, the semiconductor package 200 and the board may be aligned so that the semiconductor package 200 may be mounted at a desired position on the board.

The alignment pattern 160 may include a first portion 161 embedded on or extending into the lower surface of the pad insulation layer 122 and a second portion 162 protruding or extending away from the lower surface of the pad insulation layer 122.

The first portion 161 may be embedded on or extending into the lower surface of the pad insulation layer 122. That is, the first portion 161 may pass through at least a portion of the pad insulation layer 122. Accordingly, the first portion 161 may cover the side and upper surfaces of the alignment pattern 160. The first portion 161 may be on the edge of the pad insulation layer 122 in a plan view.

According to some embodiments, the lower surface of the first portion 161 may be at a level substantially equivalent to that of the conductive pad 121. In addition, the lower surface of the first portion 161 may be aligned on the same boundary as the lower surface of the pad insulation layer 122. The lower surface of the first portion 161 may be at a level substantially equivalent to the lower surface of the pad insulation layer 122.

The first portion 161 has a flat pad shape, and may have a circular shape in a plan view. However, the planar shape of the first portion 161 is not limited to a circular shape, and may have various shapes such as an elliptical shape and a polygonal shape.

The first portion 161 may be equal to or greater than the conductive pad 121. For example, a first width D1 of the first portion 161 in the horizontal direction may be greater than or equal to a third width D3 of the conductive pad 121 in the horizontal direction. For example, the first width D1 of the first portion 161 in the horizontal direction may be 150 to 500 μm. In addition, the first portion 161 may have a thickness substantially equivalent to that of the conductive pad 121. For example, the thickness of the first portion 161 may be 5 to 50 μm.

According to some embodiments, the first portion 161 may include a conductive material. The first portion 161 may include the same material as the conductive pad 121.

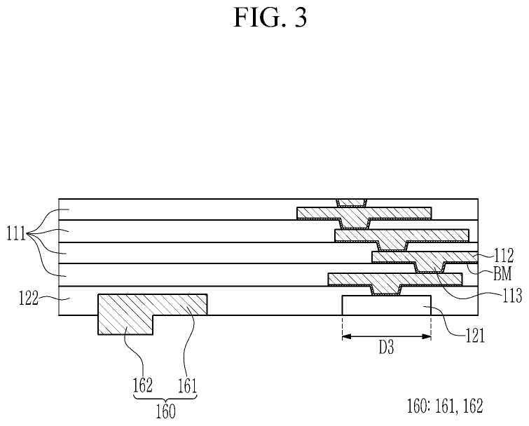

The second portion 162 may protrude or extend downward from the lower surface of the first portion 161. For example, as shown in FIG. 2, the second portion 162 may protrude or extend downward from the central portion of the first portion 161. In this case, steps may be formed on both sides of the second portion 162. However, the present disclosure is not limited thereto, as shown in FIG. 3, the second portion 162 may protrude or extend downward from one end portion of the first portion 161. In this case, a step may be formed on one side of the second portion 162. The other side of the second portion 162 may be aligned on the same boundary as the side surface of the first portion 161.

The second portion 162 may have with a smaller size than the first portion 161. For example, a second width D2 of the second portion 162 in the horizontal direction may be smaller than the first width D1 of the first portion 161 in the horizontal direction. For example, a ratio of the first width D1 of the first portion 161 in the horizontal direction to the second width D2 of the second portion 162 in the horizontal direction may be 1:4 to 1:1. Accordingly, a portion of the lower surface 161B of the first portion 161 (for example, an edge of the first portion 161) may be exposed.

In FIG. 1 and FIG. 2, the width of the second portion 162 is shown to be the same as it moves away from the first redistribution structure 110, but is not limited thereto. For example, the width of the second portion 162 may decrease as it moves away from the first redistribution structure 110. Alternatively, the side surface of the second portion 162 may include a curved surface.

According to some embodiments, in order to prevent a short circuit between the semiconductor package 200 and the board on which the semiconductor package 200 is mounted, a first thickness T1 of the second portion 162 may be ½ or less of the thickness of the solder 123. For example, the first thickness T1 of the second portion 162 may be 10 μm or less. This is because when the first thickness T1 of the second portion 162 is greater than 10 μm, the alignment pattern 160 may be in contact with the board to be short-circuited therewith while the semiconductor package 200 is mounted on the board. In addition, the first thickness T1 of the second portion 162 may be smaller than the thickness of the first portion 161.

According to some embodiments, the second portion 162 may be integrally formed with the first portion 161. That is, the second portion 162 and the first portion 161 may include the same material and may be simultaneously formed in one process. In addition, the second portion 162 may include the same material as the conductive pad. The second portion 162 and the conductive pad 121 may be simultaneously formed in one process.

The second portion 162 may have a circular shape in a plan view. However, the planar shape of the second portion 162 is not limited to a circular shape, and may have various shapes such as an elliptical shape and a polygonal shape.

According to some embodiments, the alignment pattern 160 includes the second portion 162 protruding from or extending away from the lower surface of the pad insulation layer 122, so that in the process of mounting the semiconductor package 200 on the board, efficiency of functioning as an alignment mark or align key may be relatively increased. That is, even when the pad insulation layer 122 is thickly formed to cover the lower surface of the first portion 161 of the alignment pattern 160 due to process errors, the second portion 162 protrudes or extends away from the lower surface of the pad insulation layer 122, so that the alignment pattern 160 may be accurately recognized. Accordingly, reliability may be improved by accurately aligning the semiconductor package 200 and the board so that the semiconductor package 200 is mounted at a desired position of the board.

Referring back to FIG. 1, the first semiconductor chip 130 may be mounted on the upper surface of the first redistribution structure 110. In some embodiments, the first semiconductor chip 130 may include a three-dimensional integrated circuit (3D IC) structure. In addition, in some embodiments, the first semiconductor chip 130 may include a system-on-chip (SOC). For example, the first semiconductor chip 130 may include at least one of a central processing unit (CPU), a graphic processing unit (GPU), a memory, a controller, a codec, a sensor, and a communication chip.

The first semiconductor chip 130 may be electrically connected to the first redistribution structure 110 through the connection member 141. In some embodiments, the connection member 141 may include micro bumps.

The conductive post 170 may be on the upper surface of the first redistribution structure 110. The conductive posts 170 may be positioned to extend through the molding material 180. A side surface of the conductive post 170 may be surrounded by the molding material 180. That is, the molding material 180 may be on a portion of or on a sidewall of the conductive post 170. The conductive post 170 may be between the first redistribution structure 110 and the second redistribution structure 190. The conductive post 170 may electrically connect the first redistribution structure 110 and the second redistribution structure 190. For example, the conductive post 170 may electrically connect the plurality of first redistribution vias 112 of the first redistribution structure 110 and the plurality of second redistribution vias 192 of the second redistribution structure 190.

The molding material 180 may mold the first semiconductor chip 130 and the conductive post 170 on the first redistribution structure 110.

The second redistribution structure 190 may be on the molding material 180. The second redistribution structure 190 may include a second insulation layer 191, a plurality of second redistribution vias 192 within the second insulation layer 191, and a plurality of second redistribution lines 193.

The second insulation layer 191 may protect and insulate the plurality of second redistribution vias 192 and the plurality of second redistribution lines 193. The second semiconductor chip 210 may be on the upper surface of the second insulation layer 191. The conductive post 170 and the molding material 180 may be on the lower surface of the second insulation layer 191.

The plurality of second redistribution vias 192 may be between the conductive post 170 and the plurality of second redistribution lines 193, between the plurality of second redistribution lines 193, and between the plurality of second redistribution lines 193 and a connection member 213 of the second semiconductor chip 210. The plurality of second redistribution vias 192 electrically connect the plurality of second redistribution lines 193, the conductive post 170 and the plurality of second redistribution lines 193, and the plurality of second redistribution lines 193 and the connection member 213 in the vertical direction.

The plurality of second redistribution lines 193 may extend in the horizontal direction. The plurality of second redistribution lines 193 may be between the plurality of second redistribution vias 192. The plurality of second redistribution lines 193 may electrically connect the plurality of second redistribution vias 192 in the horizontal direction.

The second semiconductor chip 210 may be on the second redistribution structure 190. The second semiconductor chip 210 may include a single chip such as a DRAM or a multiple chip such as a high bandwidth memory (HBM). The second semiconductor chip 210 may include the connection member 213 and an insulation layer 212. The connection member 213 may electrically connect the second semiconductor chip 210 and the second redistribution structure 190. In some embodiments, the connection member 213 may include a micro bump or a solder ball. The insulation layer 212 may include a plurality of openings for soldering. The insulation layer 212 may prevent the connection member 213 from being short-circuited. In some embodiments, the insulation layer 212 may include a solder resist.

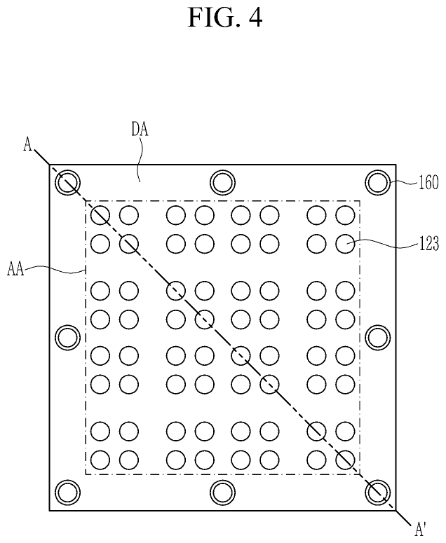

Hereinafter, a disposition structure of the conductive pad 121 and the alignment pattern 160 in a plan view will be described with reference to FIG. 4.

FIG. 4 illustrates a bottom view of a semiconductor package device according to some embodiments. In FIG. 4, the first redistribution structure 110, the conductive pad 121, and the alignment pattern 160 are shown, and the solder 123 is omitted for convenience of description.

Referring to FIG. 4, the semiconductor package 200 may include an active area AA and a dummy area DA surrounding or around the active area AA.

The conductive pad 121 may be in the active area AA. In the active area AA, the conductive pads 121 may be along a plurality of rows and columns. Since the solder 123 is on the lower surface of the conductive pad 121, the solder 123 may be in the active area AA. In addition, the first semiconductor chip 130, the conductive post 170, and the second semiconductor chip 210 may be in the active area AA.

The plurality of first redistribution lines 113 and the plurality of first redistribution vias 112 may be within the first redistribution structure 110 overlapping the active area AA. The plurality of first redistribution lines 113 and the plurality of first redistribution vias 112 may not be in the first redistribution structure 110 overlapping the dummy area DA, but are not limited thereto. In addition, the plurality of second redistribution lines 193 and the plurality of second redistribution vias 192 may be within the second redistribution structure 190 overlapping the active area AA. The plurality of second redistribution lines 193 and the plurality of second redistribution vias 192 may not be in the second redistribution structure 190 overlapping the dummy area DA, but are not limited thereto.

The alignment pattern 160 may be in the dummy area DA. In the dummy area DA, the alignment pattern 160 may surround the active area AA. That is, the alignment pattern 160 may be around the active area AA or be around or surround the conductive pad 121 in the active area AA.

Specifically, in the dummy area DA, the alignment pattern 160 may be outside each corner and each vertex of the active area AA. That is, in the dummy area DA, the alignment patterns 160 may be symmetrically positioned on two diagonal lines passing through the center of the first redistribution structure 110. In addition, the alignment pattern 160 may be parallel to a side surface of the first redistribution structure 110. Here, when the active area AA is at the center of the first redistribution structure 110, the center of the first redistribution structure 110 may coincide with the center of the active area AA. In addition, when the first semiconductor chip 130 is at the center of the first redistribution structure 110, the center of the first redistribution structure 110 may coincide with the center of the first semiconductor chip 130, but is not limited thereto.

In summary, the alignment patterns 160 may be along the edge of the first redistribution structure 110 in the dummy area DA. For example, as shown in FIG. 3, eight alignment patterns 160 may be positioned or spaced apart at the same interval along the edge of the first redistribution structure 110. However, it is not limited thereto, and the number of alignment patterns 160 of the semiconductor package 200 according to some embodiments may be adjusted as needed. That is, four alignment patterns 160 may be symmetrically positioned on two diagonal lines passing through the center of the first redistribution structure 110. Alternatively, two alignment patterns 160 may be symmetrically positioned on the diagonal line passing through the center of the first redistribution structure 110.

The first portion 161 and the second portion 162 of the alignment pattern 160 may have a circular shape in a plan view. The planar shapes of the first portion 161 and the second portion 162 are not limited to circular shapes, and may have various shapes such as elliptical shapes and polygonal shapes.

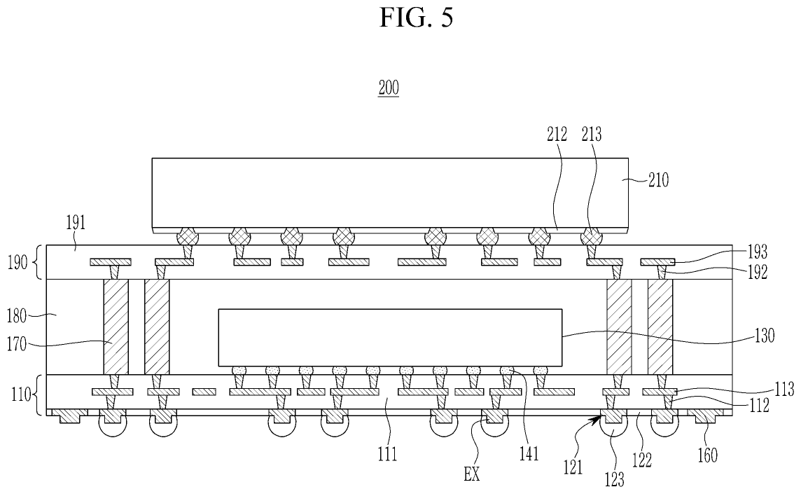

Hereinafter, a semiconductor package according to some embodiments will be described with reference to FIG. 5.

FIG. 5 illustrates a cross-sectional view of a semiconductor package according to some embodiments.

Some embodiments shown in FIG. 5 has substantially the same portions as some embodiments shown in FIG. 1 to FIG. 4, so a description thereof will be omitted and differences will be mainly described. In the present embodiment, the shape of the conductive pad 121 is different from that of the previous embodiment, and will be described below.

Referring to FIG. 5, a semiconductor package 200 according to some embodiments may include a first redistribution structure 110, an external connection structure 120, a first semiconductor chip 130, a conductive post 170, a molding material 180, a second redistribution structure 190, and a second semiconductor chip 210.

The external connection structure 120 may include a conductive pad 121, a pad insulation layer 122, a solder 123, and an alignment pattern 160.

The conductive pad 121 according to some embodiments may further include a protruding portion EX protruding or extending downward from the lower surface of the pad insulation layer 122. That is, the conductive pad 121 may include a portion embedded in, e.g., extending into, the pad insulation layer 122 and the protruding portion EX protruding or extending away from the lower surface of the pad insulation layer 122. For example, the protruding portion EX may protrude or extend downward from the central portion of the conductive pad 121. In this case, the conductive pad 121 may have steps formed on both sides of the protruding portion EX.

A width of the protruding portion EX may be smaller than a width of a portion of the conductive pad 121 embedded in, e.g., extending into, the pad insulation layer 122. For example, a ratio of the width of the portion of the conductive pad 121 embedded in, e.g., extending into, the pad insulation layer 122 to the width of the protruding portion EX in the horizontal direction may range from 1:4 to 1:1. In addition, a thickness of the protruding portion EX may be substantially the same as that of the alignment pattern 160. For example, the thickness of the protruding portion EX may be 10 μm or less.

In FIG. 5, the width of the protruding portion EX is shown to be the same as it moves away from the first redistribution structure 110, but is not limited thereto. For example, the width of the protruding portion EX may decrease as it moves away from the first redistribution structure 110. Alternatively, a side surface of the protruding portion EX may include a curved surface.

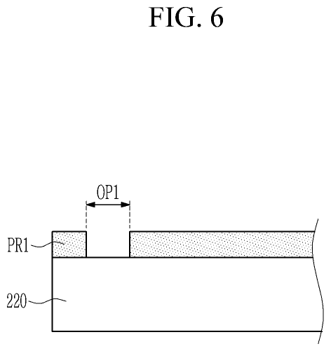

FIG. 6 to FIG. 16 illustrate cross-sectional views of a manufacturing method of a semiconductor package according to some embodiments.

FIG. 6 to FIG. 10 illustrate a manufacturing process of one alignment pattern, but are not limited thereto. That is, a plurality of alignment patterns 160 may be simultaneously manufactured through a method shown in FIG. 6 to FIG. 10.

Referring to FIG. 6, a carrier 220 is prepared, and a first photoresist PR1 having a first opening OP1 is formed on the carrier 220.

The carrier 220 may include, for example, a silicon-based material such as glass or a silicon oxide, an organic material, or another material such as an aluminum oxide, a combination of these materials, and the like.

Through a photolithography process, the first photoresist PR1 having the first opening OP1 may be deposited and patterned. Specifically, the photoresist is coated on the carrier 220. In some embodiments, the photoresist may be formed through spin coating. In some embodiments, the photoresist may include an organic polymeric resin containing a photoactive material. After that, the photoresist may be exposed and developed to pattern the first photoresist PR1 having the first opening OP1.

The first opening OP1 may be on an edge of the carrier 220. For example, the first opening OP1 may be a portion corresponding to the position of the second portion 162 of the alignment pattern 160 (see FIG. 1). That is, a plurality of first openings OP1 may be provided, and they may be along the edge of the carrier 220.

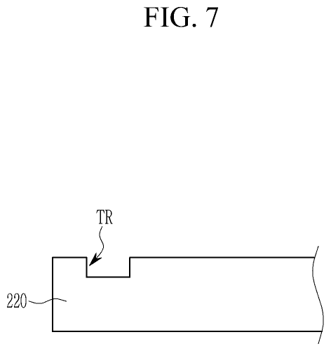

Referring to FIG. 7, a trench TR is formed by etching a portion of the carrier 220 by using the first photoresist PR1 as an etching mask. A portion of the carrier 220 exposed by the first opening OP1 may be etched to form the trench TR. The process of etching the portion of the carrier 220 may proceed through a dry etching process. The width of the trench TR is shown to be the same from the upper surface of the carrier 220 to the lower surface thereof, but is not limited thereto. For example, the width of the trench TR may decrease from the upper surface of the carrier 220 to the lower surface thereof. After that, the first photoresist PR1 may be removed.

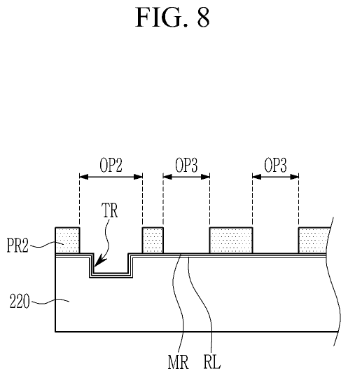

Referring to FIG. 8, a release layer RL and a metal seed layer MR may be sequentially formed on the carrier 220.

Specifically, the release layer RL may be formed on the upper surface of the carrier 220, the lower surface of the trench TR, and the inner surface of the trench TR. The release layer RL may be formed to have a constant thickness along the profile of the upper surface of the carrier 220, the lower surface of the trench TR, and the inner surface of the trench TR. The release layer RL may be made of a polymer-based material (for example, light to heat conversion (LTHC)) that may be removed along with the carrier 220 later. In some embodiments, the release layer RL may be made of an epoxy based heat-release material. In some other embodiments, the release layer RL may be formed of an ultraviolet (UV) adhesive.

After the release layer RL is formed, the metal seed layer MR may be formed on the release layer RL. This is to form the alignment pattern 160 and the conductive pad 121 through a subsequent plating process by depositing a plating seed layer on the surface in which the alignment pattern 160 and the conductive pad 121 are to be formed.

The release layer RL and the metal seed layer MR may be deposited using physical vapor deposition (PVD) or chemical vapor deposition (CVD).

Next, a second photoresist PR2 having a second opening OP2 and a third opening OP3 is formed.

Through the photolithography process, the second photoresist PR2 having the second opening OP2 and the third opening OP3 may be deposited and patterned. The process of forming the second photoresist PR2 may be substantially the same as the process of forming the first photoresist PR1.

The second opening OP2 may be formed to expose the trench TR. In this case, the sidewall of the second opening OP2 may be spaced apart from the sidewall of the trench TR. For example, the trench TR may be at a central portion of the second opening OP2. Accordingly, steps may be formed on both sides of the trench TR. In other words, the width of the second opening OP2 may be greater than the width of the trench TR. For example, a ratio of the width of the second opening OP2 to the width of the trench TR may be 1:4 to 1:1. Accordingly, a portion of the metal seed layer MR outside the trench TR may be exposed. However, it is not limited thereto, and the trench TR may be on one side of the second opening OP2. In this case, one side of the trench TR may be aligned on the same boundary as one side of the second photoresist PR2.

In addition, the second opening OP2 may be formed to be equal to or larger than the third opening OP3. For example, the width of the second opening OP2 may be 150 to 500 μm.

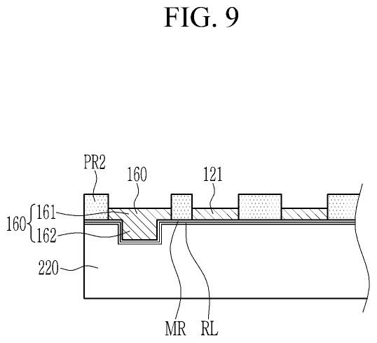

Referring to FIG. 9, the alignment pattern 160 may be formed in a space exposed by the second opening OP2, and the conductive pad 121 may be formed in a space exposed by the third opening OP3.

Specifically, the alignment pattern 160 may include the second portion 162 formed in the trench TR and the first portion 161 formed in the space exposed by the second opening OP2. Since the second portion 162 of the alignment pattern 160 is formed in the trench TR, the alignment pattern 160 may protrude or extend downward from the lower surface of the conductive pad 121. In addition, as described above, since the width of the second opening OP2 is greater than the width of the third opening OP3, the width of the alignment pattern 160 may be greater than or equal to the width of the conductive pad 121.

According to some embodiments, the alignment pattern 160 and the conductive pad 121 may include an electrically conductive material. The alignment pattern 160 and the conductive pad 121 may include the same material. For example, the alignment pattern 160 and the conductive pad 121 may include at least one of Cu, Ni, Au, Cr, Al, Ag, Zn, and Fe.

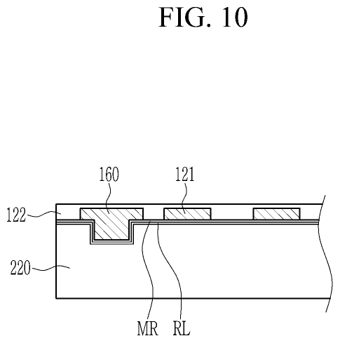

Referring to FIG. 10, the second photoresist PR2 may be removed, and the pad insulation layer 122 may be formed to cover the alignment pattern 160 and the conductive pad 121.

According to some embodiments, the pad insulation layer 122 may cover the alignment pattern 160 and the conductive pad 121. That is, the upper surface of the pad insulation layer 122 may be at a higher level than the upper surfaces of the alignment pattern 160 and the conductive pad 121. However, it is not limited thereto, and the pad insulation layer 122 may be formed between the alignment pattern 160 and the conductive pad 121 and between the conductive pads 121. In this case, the upper surface of the pad insulation layer 122 may be formed to substantially the same level as the upper surfaces of the alignment pattern 160 and the conductive pad 121.

The pad insulation layer 122 may include at least one of a silicon-based insulator such as a silicon oxide or silicon nitride, a polymer such as PBO, BCB, or polyimide, and a nitride such as PSG or BPSG.

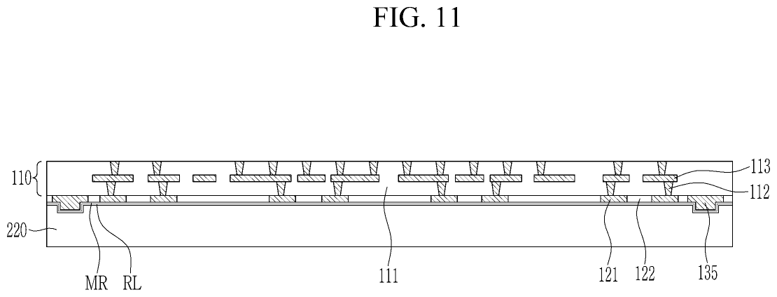

Referring to FIG. 11, the first redistribution structure 110 may be formed on the pad insulation layer 122. The first redistribution structure 110 may include a first insulation layer 111, a plurality of first redistribution lines 113, and a plurality of first redistribution vias 112 for electrically connecting the plurality of first redistribution lines 113. The first insulation layer 111 may include at least one of a silicon-based insulator such as a silicon oxide or silicon nitride, a polymer such as PBO, BCB, or polyimide, and a nitride such as PSG or BPSG. The plurality of first redistribution vias 112 and the plurality of first redistribution lines 113 may include at least one of copper, aluminum, tungsten, nickel, gold, tin, titanium, and an alloy thereof.

In the process of forming the first redistribution structure 110, first, the first insulation layer 111 is formed on the carrier 220, and a portion of the first insulation layer 111 is selectively etched to form the via holes, and a plurality of first redistribution vias 112 may be formed by filling the via holes with a conductive material. Subsequently, the first insulation layer 111 is additionally deposited on the plurality of first redistribution vias 112 and the first insulation layer 111, and the additionally deposited first insulation layer 111 is selectively etched to form openings, and a process of forming the plurality of first redistribution lines 113 by filling the opening with a conductive material may be repeatedly performed to form the first redistribution structure 110 including a plurality of layers.

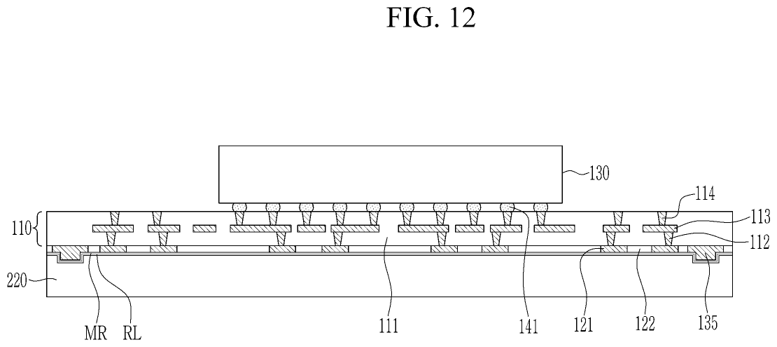

Referring to FIG. 12, the first semiconductor chip 130 may be on the first redistribution structure 110. The first semiconductor chip 130 may be bonded on the first redistribution structure 110. For example, the first semiconductor chip 130 is electrically connected to the first redistribution structure 110 through the connection member 141. Although only one first semiconductor chip 130 is shown in the drawing, the present disclosure is not limited thereto, and a plurality of semiconductor chips may be used. In some embodiments, the connection member 141 may include micro bumps.

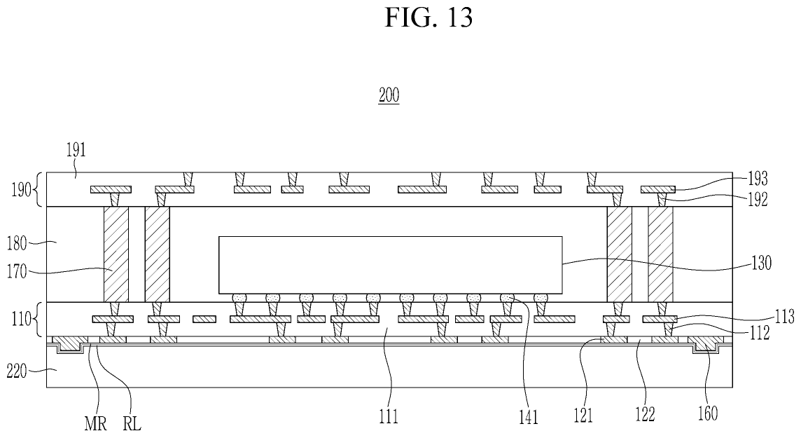

Referring to FIG. 13, the conductive post 170, the molding material 180, and the second redistribution structure 190 are formed.

First, the conductive post 170 is formed on the first redistribution structure 110 in a vertical direction. In some embodiments, the conductive post 170 may be formed by performing a sputtering process. In some embodiments, the conductive posts 170 may be formed by performing an electrolytic plating process after forming a seed metal layer. In some embodiments, the conductive post 170 may include at least one of copper, aluminum, tungsten, nickel, gold, silver, chromium, antimony, tin, titanium, and an alloy thereof.

Next, the molding material 180 is formed to cover the first semiconductor chip 130 and the conductive post 170. In some embodiments, the process of molding with the molding material 180 may include a compression molding or transfer molding process. In the process of forming the molding material 180, after forming the molding material to cover the first semiconductor chip 130 and the conductive post 170, a process of planarizing the upper surface of the molding material 180 by performing chemical mechanical polishing (CMP) may be included.

Subsequently, the second redistribution structure 190 may be formed on the molding material 180 and the conductive post 170. The second redistribution structure 190 may be formed in the same manner as the formation process of the first redistribution structure 110 described above. Accordingly, the second redistribution structure 190 may include the second insulation layer 191, the plurality of second redistribution lines 193, and the plurality of second redistribution vias 192 for electrically connecting the plurality of second redistribution lines 193.

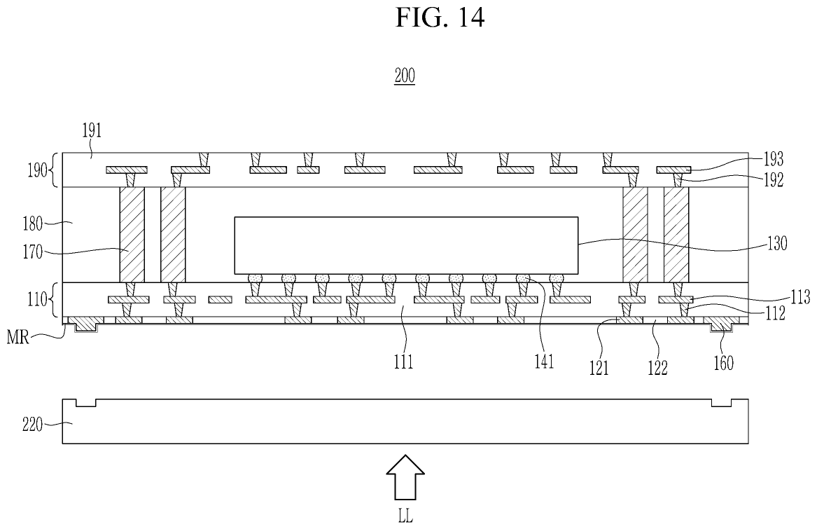

Referring to FIG. 14, the carrier 220 may be removed from the lower surface of the metal seed layer MR.

Specifically, light LL (for example, infrared) may be irradiated from the lower surface of the carrier 220 toward the upper surface thereof. For example, when the carrier 220 is made of a material having light transmissivity (for example, a silicon-based material such as glass or a silicon oxide) and when the light LL is irradiated from the lower surface of the carrier 220 toward the upper surface thereof, the light LL may be irradiated to the release layer RL. Accordingly, as described above, since the release layer RL includes a material (for example, a polymer-based material) whose adhesion is weakened by UV irradiation, the carrier 220 may be removed from the lower surface of the metal seed layer MR while the release layer RL is removed.

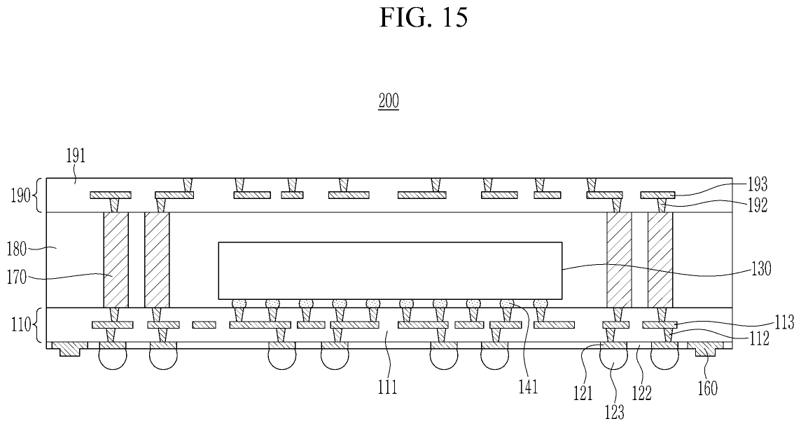

Referring to FIG. 15, the metal seed layer MR exposed on the lower surfaces of the alignment pattern 160, the conductive pad 121, and the pad insulation layer 122 may be removed, and the solder 123 may be formed.

First, the alignment pattern 160 and the conductive pad 121 may be exposed by removing the metal seed layer MR exposed on the lower surfaces of the alignment pattern 160, the conductive pad 121, and the pad insulation layer 122. In this case, the alignment pattern 160 may protrude or extend below the lower surface of the pad insulation layer 122. Accordingly, in a process of mounting the semiconductor package 200 on a board later, the efficiency of functioning as an alignment mark or an alignment key may be relatively increased. For example, even when the pad insulation layer 122 is thickly formed to cover the lower surface of the first portion 161 of the alignment pattern 160 due to process errors, the second portion 162 protrudes or extends below the lower surface of the pad insulation layer 122, so that the alignment pattern 160 may be accurately recognized.

Thereafter, the solder 123 may be formed on the lower surface of the conductive pad 121. The solder 123 may include, for example, a solder ball or a solder bump.

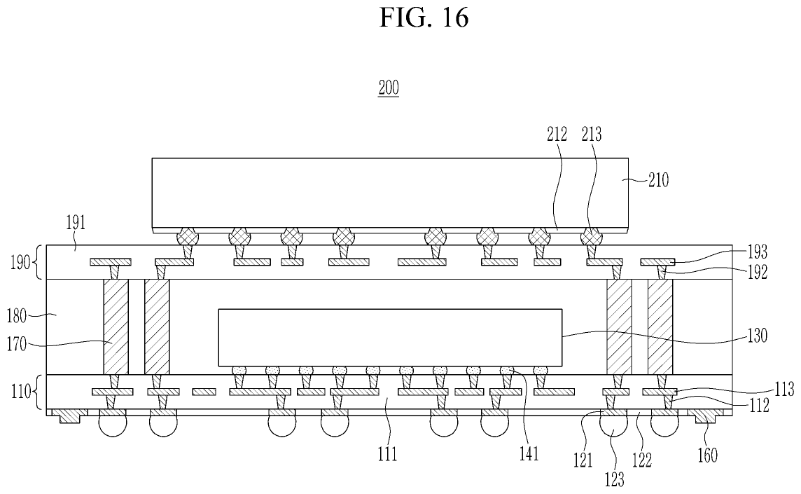

Referring to FIG. 16, in the semiconductor package according to some embodiments, the second semiconductor chip 210 may be on the second redistribution structure 190.

The second semiconductor chip 210 may be electrically connected to the second redistribution structure 190. For example, the connection member 213 at the lower end of the second semiconductor chip 210 is bonded to the plurality of second redistribution vias 192 of the second redistribution structure 190, so that the second semiconductor chip 210 may be electrically connected to the second redistribution structure 190. The connection member 213 may include solder, for example, a solder ball and a solder bump.

Although not shown in the drawings, a bonding pad may be on the upper surface of the second redistribution structure 190. The second semiconductor chip 210 may be electrically connected to the second redistribution structure 190 by bonding the connection member 213 at the lower end of the second semiconductor chip 210 to the bonding pad.

While this disclosure has been described in connection with certain embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package comprising:
a first redistribution structure;
a semiconductor chip on the first redistribution structure;
a pad insulation layer on a lower surface of the first redistribution structure;
a conductive pad extending into a lower surface of the pad insulation layer and electrically connected to the first redistribution structure; and
a plurality of alignment patterns on an edge of the pad insulation layer, each of the plurality of alignment patterns including a first portion extending into the lower surface of the pad insulation layer and a second portion extending away from the lower surface of the pad insulation layer.

2. The semiconductor package of claim 1, wherein
a width of the first portion is greater than that of the second portion.

3. The semiconductor package of claim 2, wherein
the width of the first portion is greater than that of the conductive pad.

4. The semiconductor package of claim 2, wherein
a ratio of the width of the first portion to the width of the second portion is 1:4 to 1:1.

5. The semiconductor package of claim 1, wherein
the second portion extends below a lower surface of the conductive pad.

6. The semiconductor package of claim 5, wherein
a lower surface of the first portion is at a same level as the lower surface of the conductive pad.

7. The semiconductor package of claim 1, wherein
the plurality of alignment patterns include a same material as the conductive pad.

8. The semiconductor package of claim 1, wherein
a thickness of the second portion is within 10 μm.

9. The semiconductor package of claim 1, wherein
the conductive pad further includes:
a protruding portion extending away from the lower surface of the pad insulation layer, and
a lower surface of the protruding portion is at a same level as a lower surface of the second portion.

10. The semiconductor package of claim 1, further comprising
a second redistribution structure on the semiconductor chip; and
a conductive post that physically and electrically connects the first redistribution structure and the second redistribution structure,
wherein the plurality of alignment patterns are outside the conductive post.

11. The semiconductor package of claim 10, wherein
the plurality of alignment patterns are along an edge of the first redistribution structure.

12. A semiconductor package comprising:
a first redistribution structure including an active area and a dummy area around the active area;
a semiconductor chip on the first redistribution structure in the active area;
a second redistribution structure on the semiconductor chip;
a conductive post connecting an upper surface of the first redistribution structure and a lower surface of the second redistribution structure in the active area;
a pad insulation layer on a lower surface of the first redistribution structure;
a conductive pad extending into the lower surface of the pad insulation layer and electrically connected to the first redistribution structure, in the active area;
a solder extending away from a lower surface of the conductive pad; and
a plurality of alignment patterns, each of the plurality of alignment patterns including a first portion extending into the lower surface of the pad insulation layer and a second portion extending away from the lower surface of the pad insulation layer, in the dummy area,
wherein a width of the first portion is greater than that of the second portion.

13. The semiconductor package of claim 12, wherein
the plurality of alignment patterns are on a diagonal passing through a center of the semiconductor chip, in the dummy area.

14. A manufacturing method of a semiconductor package, comprising:
patterning a trench on one surface of a carrier substrate;
forming a mask pattern having a first opening exposing the trench on the carrier substrate;
forming an alignment pattern on the trench exposed by the first opening;
forming a first redistribution structure on the alignment pattern; and
mounting a semiconductor chip on the first redistribution structure.

15. The manufacturing method of the semiconductor package of claim 14, wherein a width of the first opening is greater than that of the trench.

16. The manufacturing method of the semiconductor package of claim 14, wherein
the mask pattern further has a second opening exposing a portion of the carrier substrate, and
the forming of the alignment pattern further includes forming a conductive pad on a portion of the carrier substrate exposed by the second opening.

17. The manufacturing method of the semiconductor package of claim 16, wherein
a width of the second opening is smaller than that of the first opening.

18. The manufacturing method of the semiconductor package of claim 16, wherein
the alignment pattern is thicker than the conductive pad.

19. The manufacturing method of the semiconductor package of claim 14, further comprising:
after the patterning of the trench,
sequentially forming a release layer and a seed metal layer on an upper surface of the carrier substrate and on an inner surface and a lower surface of the trench.

20. The manufacturing method of the semiconductor package of claim 16, further comprising
after the forming of the alignment pattern and the conductive pad,
forming a pad insulation layer covering the alignment pattern and the conductive pad.
